(19) United States
(12) Patent Application Publication
(10) Pub. No.: US 2012/0113590 A1
(43) Pub. Date: May 10, 2012

(54) ELECTRONIC SYSTEM WITH EHD AIR MOVER VENTILATION PATH ISOLATED FROM INTERNAL AIR PLENUM

(75) Inventors: Matthew Schwiebert, Cupertino, CA (US); Ron Goldman, Oakland, CA (US); Kenneth Honer, Santa Clara, CA (US); Guilian Gao, San Jose, CA (US); Yan Zhang, San Jose, CA (US); Nels Jewell-Larsen, San Jose, CA (US)

(73) Assignee: TESSERA, INC., San Jose, CA (US)

(21) Appl. No.: 13/293,946

(22) Filed: Nov. 10, 2011

Related U.S. Application Data
(60) Provisional application No. 61/412,310, filed on Nov. 10, 2010.

(51) Int. Cl. H05K 7/20; F28F 13/00

(52) U.S. Cl. 361/694; 165/120

(57) ABSTRACT

An electronic system including an enclosure and an internal air plenum within the enclosure. At least one component of the electronic system within the enclosure evolves heat and has a surface exposed to the internal air plenum. The enclosure has inlet and outlet ventilation boundaries together with an EHD air mover disposed therein to motivate airflow along a flow path between the inlet and outlet ventilation boundaries, wherein the flow path is substantially excluded from the internal air plenum by a barrier.

### CROSS-REFERENCE TO RELATED APPLICATIONS

This application claims priority to U.S. Patent Application No. 61/412,310 filed Nov. 10, 2010, which is incorporated herein in its entirety.

### BACKGROUND

Many devices or systems, whether electronic, optical, mechanical, may include, provide or require forced flow of air or some other ambient fluid. In some cases, the forced flow is useful to cool or otherwise moderate heat evolved by thermal sources within the device or system. In such cases, cooling or thermal moderation may help prevent device overheating, reduce thermal hotspots, provide desired thermal stability for temperature sensitive devices, improve long term reliability or provide other benefits. In some cases, forced flow is a primary function of the device or system.

It is known in the art to provide cooling airflow with the use of fans, blowers or other similar moving mechanical devices; however, such devices generally have limited operating lifetimes, tend to produce undesired noise or vibration, consume power or suffer from other design problems. In addition, such devices can often impose constraints of geometry form factor and/or layout of systems for which they provide cooling airflows. These constraints can be particularly problematic in modern consumer electronics devices for which size and “thinness,” are important market differentiators.

In some applications, the use of an ion flow air mover device, such as an electrohydrodynamic (EHD) device or electro-fluid dynamic (EFD) device, may result in improved cooling efficiency, reduced vibrations, power consumption, electronic device temperatures, and noise generation. In such deployments, an EHD air mover may reduce costs, allow designs to reduce device size, thickness or volume, and may in some cases improve electronic device performance and/or user experience.

EHD-type air movers and other similar devices can produce ions, charged particulate and ozone, as well as electromagnetic interference (EMI). Some electronic system components may be adversely affected by ions, charged particulate or ozone that migrate or diffuse throughout a system or enclosure. Likewise, transient arcing or sparking events may present EMI mitigation challenges. In some cases, the potential for adverse effects may be accentuated as system form factors and standoffs decrease and as EHD-type air movers or other similar devices are advantageously situated to provide airflows precisely where needed in such designs. Accordingly, improvements are sought in mitigating exposure or the effects of exposure of electronic system components to ions, charged particulate, ozone and/or EMI.

### SUMMARY

The present invention relates generally to integration of EHD-type air movers with electronic systems, and in particular, to isolation of electronic components and/or sensitive materials from ions, charged particulates and/or ozone that may be generated during operation. In particular, it has been discovered that an electrohydrodynamic (EHD) air mover may be used to cool an electronic system while an internal air plenum encompassing components of the electronic system is substantially sealed from the airflow of the EHD air mover.

In some embodiments in accordance with the present invention, an electronic system includes an enclosure and an internal air plenum within the enclosure. At least one component within the enclosure has a surface exposed to the internal air plenum. The enclosure has inlet and outlet ventilation boundaries together with an EHD air mover disposed therein to motivate airflow along a flow path between the inlet and outlet ventilation boundaries. The flow path is substantially excluded or sealed from the internal air plenum, e.g., by a barrier.

In some implementations, the at least one component constitutes a thermal source that, during operation of the electronic system, evolves heat. The system includes, in some implementations, a heat transfer path across the seal or barrier from the thermal source to the flow path. In some implementations, the seal substantially precludes infiltration of ozone from the EHD air mover or the flow path into the internal air plenum.

In some implementations, the electronic system further includes a mechanical air mover configured to positively pressurize the internal air plenum during operation of the electronic system.

In some implementations, EMI shielding is provided between the internal air plenum and the EHD air mover to mitigate the effects of changing electromagnetic fields. In some implementations, the internal air plenum is substantially sealed against intrusion of at least one of ions, liquid or gas from the flow path.

In some implementations, a nominal breach in the barrier or seal between the airflow and the internal air plenum is positioned upstream of the EHD air mover. In some cases, the nominal breach accounts for less than about five percent of air movement through the internal air plenum.

In some implementations, the internal air plenum is substantially sealed against intrusion of at least one of a cleaning agent and a sterilizing agent introduced into the airflow. In some applications, the electronic system is configured for use in one of a medical and a clean-room environment and the EHD air mover and airflow are configured and arranged to be sterilized periodically or at successive times during its operational life. In some implementations, the EHD air mover is removable and replaceable, e.g., to allow for sterilization of the EHD air mover separate from the electronic system.

In some implementations, a pressure differential is maintained across a fluid port between the internal air plenum and the airflow during operation to substantially mitigate diffusion of the airflow into the internal air plenum.

In some implementations, a portion of the barrier is selectively fluid permeable in a first state and selectively closeable during at least one of a period of operation of the electronic system and a period of exposure of the electronic system to a sterilization agent.

In some implementations, a heat pipe is thermally connected to the component and forms a portion of the barrier between the internal air plenum and the airflow.

In some implementations, one or more electronic component forms a portion of the barrier.

In some implementations, at least a portion of the airflow flows through a duct extending through a central region of the internal air plenum.

In some implementations, the airflow passes over a major surface of the internal air plenum.

In some implementations, an ozone reducing material is exposed to the airflow downstream of the EHD air mover.

Another aspect of the invention features, in some applications, a method of motivating airflow through an electronic system. The method includes providing an enclosure and an internal air plenum within the enclosure and operating at least one component of the electronic system within the enclosure, the component evolving heat and having a surface exposed to the internal air plenum. The method includes operating an EHD air mover disposed within the enclosure to motivate airflow along a flow path between inlet and outlet ventilation boundaries to remove heat evolved by the component, wherein the flow path is substantially excluded from the internal air plenum by a barrier.

In some applications, the barrier is at least partially defined by a pressure differential between air in the internal air plenum and the airflow.

In some applications, the method includes pressurizing the internal air plenum to exclude the airflow.

In some applications, the method includes allowing for nominal exchange between the airflow and the internal air plenum upstream of the EHD air mover.

In some applications, the method includes exposing at least a portion of the flow path to a sterilization agent; wherein the barrier substantially excludes the sterilization agent from the internal air plenum.

In some applications, the method includes removing the EHD air mover from the electronic system for separate sterilization or replacement of the EHD air mover.

These and other embodiments will be understood with reference to the description herein, the drawings and the appended claims.

### BRIEF DESCRIPTION OF THE DRAWINGS

The present invention may be better understood, and its numerous objects, features, and advantages made apparent to those skilled in the art by referencing the accompanying drawings.

FIG. 1A is a depiction of certain basic principles of electrohydrodynamic (EHD) fluid flow. FIG. 1B depicts a side cross-sectional view of an illustrative EHD air mover device.

FIGS. 2, 3 and 4 depict illustrative top views of various EHD air mover, airflow and internal air plenum implementations.

The use of the same reference symbols in different drawings indicates similar or identical items.

### DESCRIPTION

Devices built using the principle of the ionic movement of a fluid are variously referred to in the literature as ionic wind machines, electric wind machines, corona wind pumps, electro-fluid-dynamics (EFD) devices, electrostatic fluid accelerators (EFAs), electrohydrodynamic (EHD) thrusters and EHD gas pumps. Some aspects of the technology have also been exploited in devices referred to as electrostatic air cleaners or electrostatic precipitators. In general, EHD technology uses ion flow principles to move fluids (e.g., air molecules). Basic principles of EHD fluid flow are reasonably well understood by persons of skill in the art. Accordingly, a brief illustration of ion flow using corona discharge principles in a simple two electrode system sets the stage for the more detailed description that follows.

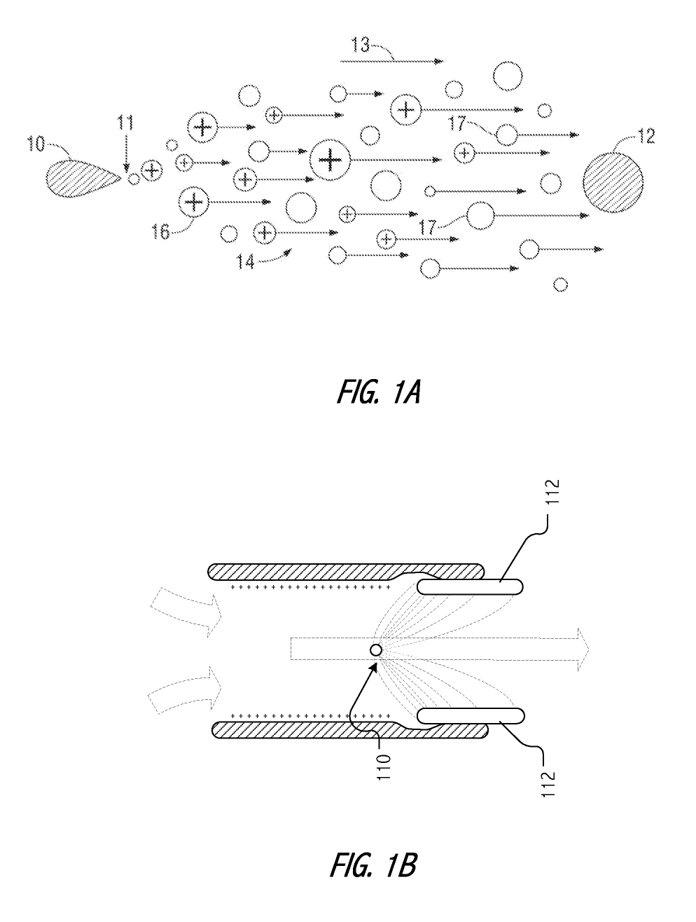

With reference to the illustration in FIG. 1A, EHD principles include applying a high intensity electric field between a first electrode 10 (often termed the “corona electrode,” the “corona discharge electrode,” the “emitter electrode” or just the “emitter”) and a second electrode 12. Fluid molecules, such as surrounding air molecules, near the emitter discharge region 11, become ionized and form a stream 14 of ions 16 that accelerate toward second electrode 12, colliding with neutral fluid molecules 17. During these collisions, momentum is imparted from the stream 14 of ions 16 to the neutral fluid molecules 17, inducing a corresponding movement of fluid molecules 17 in a desired fluid flow direction, denoted by arrow 13, toward second electrode 12. Second electrode 12 may be variously referred to as the “accelerating,” “attracting,” “target” or “collector” electrode. While stream 14 of ions 16 is attracted to, and generally neutralized by, second electrode 12, neutral fluid molecules 17 continue past second electrode 12 at a certain velocity. The movement of fluid produced by EHD principles has been variously referred to as “electric,” “corona” or “ionic” wind and has been defined as the movement of gas induced by the movement of ions from the vicinity of a high voltage discharge electrode 10.

In general, practical EHD air mover implementations may include electrode geometries, channel designs and field shaping features, EMI shielding and/or duct work and heat transfer surfaces that have been adapted for a given application or deployment. FIG. 1B depicts a side cross-sectional view of an illustrative EHD air mover that has been developed for thin form factor consumer electronics device applications. Although embodiments in accordance with the present inventions need not employ EHD air mover designs akin to that illustrated in FIG. 1B or described elsewhere herein, persons of ordinary skill in the art will appreciate suitable adaptations of the techniques described herein to systems that include EHD air movers of alternative design.

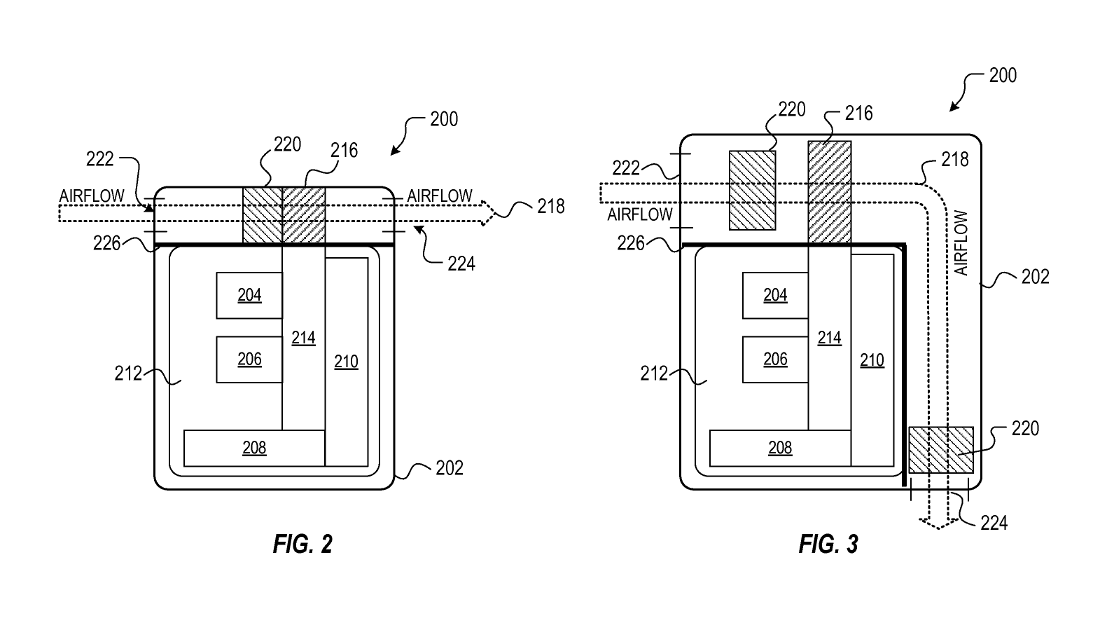

Accordingly, in view of the foregoing, and without limitation, in the EHD air mover illustrated in FIG. 1B, a high intensity electric filed is established between an emitter electrode 110 and a pair of collector electrodes 112. Although power supply connections are omitted for clarity, exemplary field lines show the direction in which individual ions are accelerated to motivate a net downstream fluid flow 13. Further detail and variations on the basic EHD air mover design illustrated are provided with reference to FIGS. 2, 3, and 4, which follow.

With reference to FIG. 2, an electronic system 200 includes an enclosure 202 housing various electronic components, e.g., a microprocessor 204, video graphics card 206, battery 208 and a display illumination source 210, any or all of which may generate heat during operation of the electronic system 200. Enclosure 202 further includes an internal air plenum 212 housing one or more of the electronic components. A heat pipe 214 or other heat path conveys heat from the one or more electronic components within the internal air plenum 212 to a heat transfer surface 216 positioned within an airflow 218 motivated by an EHD air mover 220. Note that heat pipe 214 is illustrated schematically and based on the description herein, persons of ordinary skill in the art will recognize topological variations suitable for heat transfer needs of particular systems. The enclosure 202 has inlet and outlet ventilation boundaries 222 and 224 and the EHD air mover 202 motivates airflow along a flow path between the inlet and outlet ventilation boundaries 222 and 224. The flow path or airflow 218 is substantially excluded or sealed from the internal air plenum 212e, e.g., by a barrier 226.

The seal or barrier may be provided by rigid or semi-rigid wall(s) defining a barrier 226 between the internal air plenum 212 and the airflow 218. In some implementations, the barrier 226 may be a substantially fluid-impermeable, flexible barrier. In some implementations, pressure within the internal air plenum or a pressure differential between the internal air plenum and airflow may serve to further mitigate intrusion of the airflow 218 into the internal air plenum 212.

The internal air plenum 212 is substantially sealed from airflow 218. Thus, although heat is effectively conveyed through or across barrier 226 outside of the internal air plenum and into the airflow, ingress of ions, charged particulates and ozone is substantially excluded from the internal air plenum 212. EMI shielding may also be provided between the EHD air mover 220 and the internal air plenum 212. Note that in some cases, a nominal amount of diffusion or other flow may be permitted between airflow 218 and internal air plenum 212, preferably upstream of the EHD air mover(s) 220. For example, in some embodiments, a small percentage (less than about 5%) of airflow 218 may traverse the internal air plenum 212 through incidental or purposeful breaches in barrier 226.

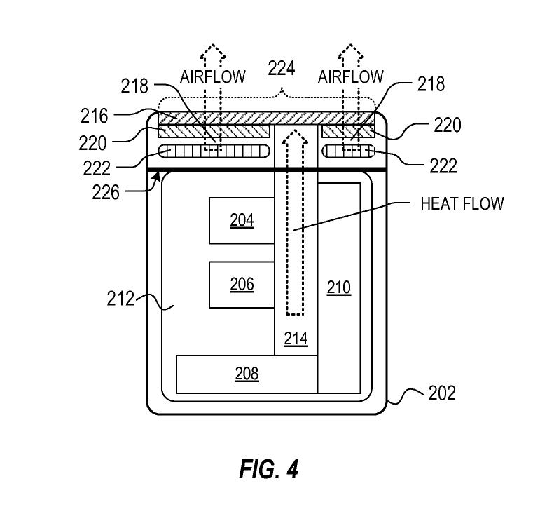

Any of a variety of airflow configurations may be provided. For example, and with reference to FIG. 2, airflow 218 may run substantially parallel to one or more edge portions of internal air plenum 212. Airflow 218 may run along multiple edges or sides of internal air plenum 212 (see e.g., FIG. 3). In some embodiments, airflow(s) 218 may travel a short path through enclosure 202. For example as illustrated in FIG. 4, entering through one or more inlet ventilation boundaries 222 on a major surface of enclosure 202 and exiting one or more outlet ventilation boundaries 224 on an adjacent edge. In some variations (not specifically shown), airflow 218 (or a portion thereof) may be directed over a broad surface of internal air plenum 212 or through a central chamber extending through the internal air plenum.

EMI shielding may be provided adjacent electrodes of the EHD air mover 220. As illustrated in FIG. 3, EHD air movers 220 may be provided both to push and pull airflow 218 between inlet and outlet boundaries 222 and 224. Ozone reducing material may be provided downstream of the EHD air mover 220.

In some implementations, enclosure and/or duct surfaces along the flow path can be provided with an ozone reducing material. In some applications, an ozone catalytic or reactive material can be provided on surfaces exposed to the internal air plenum. Similarly, ozone resistive or tolerant coatings can be provided on surfaces exposed to the internal air plenum. Ozone reducing materials can include ozone catalysts, ozone binders, ozone reactants or other materials suitable to react with, bind to, or otherwise reduce or sequester ozone. In some implementations, the ozone reducing material is a catalyst selected from a group that includes: manganese (Mn); manganese dioxide (MnO₂); gold (Au); silver (Ag); silver oxide (Ag₂O); and an oxide of nickel (Ni); and an oxide of manganese preparation. Ozone reducing material can be applied to internal enclosure surfaces and/or to the surface of electronic components within enclosure. Ozone reducing material can additionally be applied to electronic system components. Similarly, surfaces of any number of the electronic components within enclosure, and even internal enclosure surfaces can be provided with ozone tolerant or ozone resistant coating to mitigate the effects of ozone.

In some applications, the electronic system 200 may be used in a medical environment, clean-room or other optimally sterile environment. The airflow path and EHD air mover 220 can be designed to accommodate immersion or other exposure to sterilizing agents such as alcohol, UV lights and the like, e.g., to prevent cross-contamination between different environments. It may be desirable to protect the components within the internal air plenum from exposure to the sterilizing agent via segregation of the air within the internal air plenum and the airflow.

In some implementations, EHD air mover 220 is removable and/or replaceable, e.g., to allow for separate sterilization or replacement of EHD air mover 220.

### Additional Embodiments

Some implementations of thermal management systems described herein employ EFA or EHD devices to motivate flow of a fluid, typically air, based on acceleration of ions generated as a result of corona discharge. Other implementations may employ other ion generation techniques and will nonetheless be understood in the descriptive context provided herein. Using heat transfer surfaces, heat dissipated by electronics (e.g., microprocessors, graphics units, etc.) and/or other electronic system components can be transferred to the fluid flow and exhausted. Heat transfer paths, e.g., heat pipes, are provided to transfer heat from a heat source within the internal plenum to a location(s) within the enclosure where airflow motivated by an EHD device(s) flows over heat transfer surfaces to dissipate the heat.

In some implementations, an EFA or EHD air cooling system or other similar ion action device may be integrated into an operational system such as a laptop, tablet or desktop computer, a projector or video display device, etc., while other implementations may take the form of subassemblies. Various features may be used with different devices including EFA or EHD devices such as air movers, film separators, film treatment devices, air particulate cleaners, photocopy machines and cooling systems for electronic devices such as computers, laptops and handheld devices. One or more EHD cooled devices can include one of a computing device, projector, copy machine, fax machine, printer, radio, audio or video recording device, audio or video playback device, communications device, charging device, power inverter, light source, heater, medical device, home appliance, power tool, toy, game console, set-top console, television, and video display device.

While the foregoing represents a description of various implementations of the invention, it is to be understood that the claims below recite the features of the present invention, and that other implementations, not specifically described hereinabove, fall within the scope of the present invention.

What is claimed is:

1. An electronic system comprising:
an enclosure;
an internal air plenum within the enclosure; and
at least one component of the electronic system within the enclosure having a surface exposed to the internal air plenum,
wherein the enclosure has inlet and outlet ventilation boundaries together with an EHD air mover disposed therein to motivate airflow along a flow path between the inlet and outlet ventilation boundaries, wherein the flow path is substantially excluded from the internal air plenum by a barrier.

2. The electronic system of claim 1,
wherein the at least one component constitutes a thermal source that, during operation of the electronic system, produces heat; and
further comprising a heat transfer path from the thermal source in the internal air plenum to the flow path.

3. The electronic system of claim 1,
wherein the barrier substantially precludes infiltration of ozone evolved by the EHD air mover from the flow path into the internal air plenum.

4. The electronic system of claim 1, further comprising:
a mechanical air mover configured to positively pressurize the internal air plenum during operation of the electronic system.

5. The electronic system of claim 1, further comprising:
EMI shielding between the internal air plenum and the EHD air mover.

6. The electronic system of claim 1,
wherein the internal air plenum is substantially sealed against intrusion of at least one of ions, liquid and gas from the flow path.

7. The electronic system of claim 1,
wherein a nominal breach in the barrier between the airflow and the internal air plenum is positioned upstream of the EHD air mover.

8. The electronic system of claim 7,
wherein the nominal breach accounts for less than about five percent of air movement through the internal air plenum.

9. The electronic system of claim 1,
wherein the internal air plenum is substantially sealed against intrusion of at least one of a cleaning agent and a sterilizing agent introduced into the airflow.

10. The electronic system of claim 9,
wherein the electronic system is configured for use in one of a medical and a clean-room environment and the EHD air mover and airflow are configured and arranged to be periodically sterilized.

11. The electronic system of claim 1,
wherein the EHD air mover is removable from the system for at least one of replacement, maintenance and sterilization.

12. The electronic system of claim 1,
wherein a pressure differential is maintained across a fluid port between the internal air plenum and the airflow during operation to substantially mitigate diffusion of the airflow into the internal air plenum.

13. The electronic system of claim 1,
wherein a portion of the barrier is selectively fluid permeable in a first state and selectively closeable during at least one of a period of operation of the electronic system and a period of exposure of the electronic system to a sterilization agent.

14. The electronic system of claim 1,
wherein a heat pipe is thermally connected to the component and forms a portion of the barrier between the internal air plenum and the airflow.

15. The electronic system of claim 1,
wherein the component forms a portion of the barrier.

16. The electronic system of claim 1,
wherein at least a portion of the airflow flows through a duct extending through a central region of the internal air plenum.

17. The electronic system of claim 1,
wherein the airflow passes over a major surface of the internal air plenum.

18. The electronic system of claim 1, further comprising:
ozone reducing material exposed to the airflow downstream of the EHD air mover.

19. A method of motivating airflow through an electronic system, the method comprising:
providing an enclosure and an internal air plenum within the enclosure;
operating at least one component of the electronic system within the enclosure, the component evolving heat and having a surface exposed to the internal air plenum;
operating an EHD air mover disposed within the enclosure to motivate airflow along a flow path between inlet and outlet ventilation boundaries to remove heat evolved by the component, wherein the flow path is substantially excluded from the internal air plenum by a barrier.

20. The method of claim 19,
wherein the barrier is at least partially defined by a pressure differential between air in the internal air plenum and the airflow.

21. The method of claim 19, further comprising:
pressurizing the internal air plenum to exclude the airflow.

22. The method of claim 19, further comprising:
allowing for nominal exchange between the airflow and the internal air plenum upstream of the EHD air mover.

23. The method of claim 19, further comprising:
exposing at least a portion of the flow path to a sterilization agent;
wherein the barrier substantially excludes the sterilization agent from the internal air plenum.
